(19) United States
(12) Patent Application Publication
(10) Pub. No.: US 2026/0005486 A1
(43) Pub. Date: Jan. 1, 2026

(54) LIGHT-EMITTING DEVICE, LIGHT-EMITTING MODULE, AND MOBILE DEVICE

(71) Applicant: NICHIA CORPORATION, Anan-shi (JP)

(72) Inventor: Akira HORI, Tokushima-shi (JP)

(73) Assignee: NICHIA CORPORATION, Anan-shi (JP)

(21) Appl. No.: 19/250,192

(22) Filed: Jun. 26, 2025

(30) Foreign Application Priority Data
Jun. 28, 2024 (JP) 2024-104574
Jan. 29, 2025 (JP) 2025-012892

(51) Int. Cl. H01S 5/02257; H01S 5/00

(52) U.S. Cl. CPC H01S 5/02257; H01S 5/0078

(57) ABSTRACT

A light-emitting device includes: a light-emitting element; a light-transmissive member disposed on the light-emitting element and having an upper surface, a lower surface, and a first recessed portion that opens at the upper surface; and a first light-shielding member located on the upper surface of the light-transmissive member. A lateral surface of the first recessed portion of the light-transmissive member is exposed from the first light-shielding member.

### CROSS-REFERENCE TO RELATED APPLICATIONS

This application is based on and claims priority to Japanese Patent Application No. 2024-104574, filed on Jun. 28, 2024, and Japanese Patent Application No. 2025-012892, filed on Jan. 29, 2025. The entire contents of these applications are incorporated herein by reference.

### BACKGROUND

The present disclosure relates to a light-emitting device, a light-emitting module, and a mobile device.

Japanese Patent Publication No. 2019-125632 describes a light-emitting device with an improved external appearance. The light-emitting device includes a light-emitting element, a wavelength conversion member disposed on the light-emitting element, a reflecting member covering the lateral surfaces of the light-emitting element and the lateral surfaces of the wavelength conversion member, and a covering member covering the upper surface of the wavelength conversion member and the upper surface of the reflecting member and having a body color the same as or similar to a body color of the wavelength conversion member.

### SUMMARY

An object of one embodiment of the present disclosure is to provide a light-emitting device that is less likely to be visually recognized from the outside. Further, an object of one embodiment of the present disclosure is to provide a light-emitting module including the light-emitting device, and to provide a mobile device.

A light-emitting device according to one embodiment of the present disclosure includes: a light-emitting element; a light-transmissive member disposed over the light-emitting element and having an upper surface, a lower surface, and a first recessed portion that opens at the upper surface; and a first light-shielding member located on the upper surface of the light-transmissive member. A lateral surface of the first recessed portion of the light-transmissive member is exposed from the first light-shielding member.

A light-emitting module according to one embodiment of the present disclosure includes: a light-emitting device; and a lens disposed over the light-emitting device. The light-emitting device includes a light-emitting element, a light-transmissive member disposed over the light-emitting element and having an upper surface, a lower surface, and a first recessed portion that opens at the upper surface, and a first light-shielding member located on the upper surface of the light-transmissive member. A lateral surface of the first recessed portion of the light-transmissive member is exposed from the first light-shielding member.

A mobile device according to one embodiment of the present disclosure includes: a display; and a light-emitting module disposed on a same side of the mobile device as the display in a top view. The light-emitting module includes a light-emitting device, and a lens disposed over the light-emitting device. The light-emitting device includes a light-emitting element, a light-transmissive member disposed over the light-emitting element and having an upper surface, a lower surface, and a first recessed portion that opens at the upper surface, and a first light-shielding member located on the upper surface of the light-transmissive member. A lateral surface of the first recessed portion of the light-transmissive member is exposed from the first light-shielding member.

### BRIEF DESCRIPTION OF THE DRAWINGS

FIG. 1 is a top view schematically illustrating a mobile device according to an embodiment;

FIG. 2 is a cross-sectional view schematically illustrating a light-emitting module taken along line II-II of FIG. 1;

FIG. 3 is a top view schematically illustrating a light-emitting device included in the light-emitting module according to the embodiment;

FIG. 4 is a cross-sectional view schematically illustrating the light-emitting device taken along line IV-IV of FIG. 3;

FIG. 5 is a cross-sectional view schematically illustrating the light-emitting device taken along line V-V of FIG. 3;

FIG. 6 is a schematic cross-sectional view illustrating an example of a method of manufacturing the light-emitting device according to the embodiment;

FIG. 7 is a schematic cross-sectional view illustrating the example of the method of manufacturing the light-emitting device according to the embodiment;

FIG. 8 is a schematic cross-sectional view illustrating the example of the method of manufacturing the light-emitting device according to the embodiment;

FIG. 9 is a schematic cross-sectional view illustrating the example of the method of manufacturing the light-emitting device according to the embodiment;

FIG. 10 is a schematic cross-sectional view illustrating the example of the method of manufacturing the light-emitting device according to the embodiment;

FIG. 11 is a top view schematically illustrating a light-emitting device according to a first modification of the embodiment;

FIG. 12 is a cross-sectional view schematically illustrating the light-emitting device taken along line XII-XII of FIG. 11;

FIG. 13 is a top view schematically illustrating a light-emitting device according to a second modification of the embodiment;

FIG. 14 is a cross-sectional view schematically illustrating the light-emitting device taken along line XIV-XIV of FIG. 13;

FIG. 15 is a top view schematically illustrating a light-emitting device according to a third modification of the embodiment; and

FIG. 16 is a cross-sectional view schematically illustrating the light-emitting device taken along line XVI-XVI of FIG. 15.

### DETAILED DESCRIPTION

A light-emitting device, a light-emitting module, and a mobile device according to an embodiment of the present disclosure will be described in detail with reference to the accompanying drawings. The embodiment described below illustrates a light-emitting device, a light-emitting module, and a mobile device that embody technical ideas underlying the present invention, but the present invention is not limited to the described embodiment. In addition, unless otherwise specified, the dimensions, materials, shapes, relative arrangements, and the like of components described in the embodiment are not intended to limit the scope of the present disclosure thereto, but are described as examples. The sizes, positional relationships, and the like, of members illustrated in the drawings may be exaggerated for a better understanding of the structures. Further, in the following description, the same names and reference numerals refer to the same or similar members, and a detailed description thereof will be omitted as appropriate. An end view illustrating only a cut surface may be used as a cross-sectional view.

In the drawings, directions may be indicated by an X-axis, a Y-axis, and a Z-axis. The X-axis, the Y-axis, and the Z-axis are orthogonal to one another. A direction indicated by an arrow in the X-axis direction is referred to as a +X direction or a +X side, and a direction opposite to the +X direction is referred to as a −X direction or a −X side. A direction indicated by an arrow in the Y-axis direction is referred to as a +Y direction or a +Y side, and a direction opposite to the +Y direction is referred to as a −Y direction or a −Y side. A direction indicated by an arrow in the Z-axis direction is referred to as a +Z direction or a +Z side, and a direction opposite to the +Z direction is referred to as a −Z direction or a −Z side. Further, the term “top view” as used in the embodiment refers to viewing an object from the +Z side. However, these directions do not limit the orientations of the light-emitting device, the light-emitting module, and the mobile device during use, and the orientations of the light-emitting device, the light-emitting module, and the mobile device are discretionary. Further, in the embodiment, a surface of the object as viewed from the +Z side is referred to as an “upper surface,” and a surface of the object as viewed from the −Z side is referred to as a “lower surface.” In the embodiment described below, each of “along the X-axis,” “along the Y-axis,” and “along the Z-axis” includes a case where the object is at an inclination within a range of ±10° with respect to the corresponding one of the axes. Further, in the embodiment, the term “orthogonal” may include an error within ±10° of 90°.

Further, in the present disclosure, unless otherwise specified, the term “polygonal shape” such as a rectangular shape encompasses polygonal shapes in which corners of the polygonal shapes are rounded, chamfered, beveled, coved, or the like. Furthermore, the term “polygonal shape” not only encompasses polygonal shapes in which corners (ends of sides) are modified, but also encompasses polygonal shapes in which intermediate portions of the sides are modified. In other words, shapes that are based on polygonal shapes and partially modified are construed as “polygonal shapes” as described in the present disclosure.

The same applies not only to polygonal shapes but also to terms representing specific shapes such as trapezoidal shapes, circular shapes, projecting portions, or recessed portions. The same also applies when referring to sides forming such a shape. That is, even when a corner or an intermediate portion of a certain side is modified, the “side” is construed as including the modified portion.

Further, the term “cover” is not limited to a case of direct contact, but also includes a case of indirectly covering a member via another member, for example. The term “disposing” is not limited to a case of direct contact, but also includes a case of indirectly disposing a member via another member, for example. The term “on” encompasses both a configuration in which a member is disposed directly on and in contact with another member and a configuration in which a member is disposed on another member with a space or an intervening member interposed therebetween.

### Embodiment

### Mobile Device

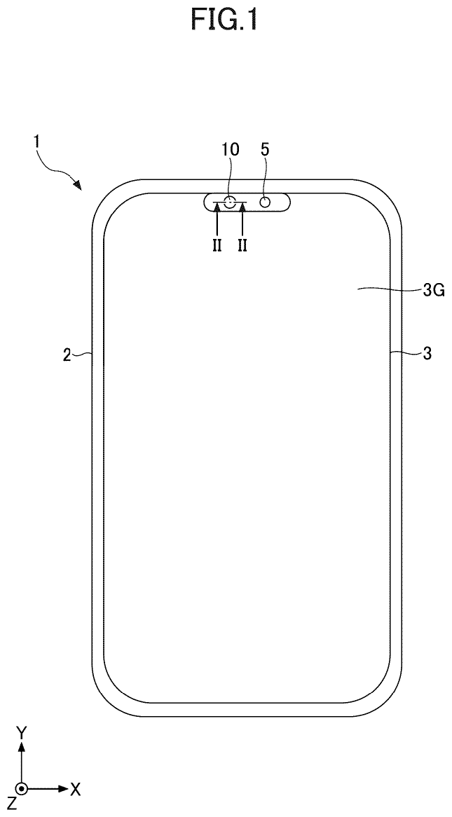

An example of an overall configuration of a mobile device 1 according to an embodiment will be described with reference to FIG. 1. FIG. 1 is a top view schematically illustrating the mobile device 1 according to the embodiment. Examples of the mobile device 1 include a smartphone and a tablet device. However, the mobile device 1 is not limited to a smartphone or a tablet device.

As illustrated in FIG. 1, the mobile device 1 includes a housing 2, a display 3, and a light-emitting module 10. The mobile device 1 may further include other components such as a camera 5. The camera 5 includes an imaging element that receives reflected light from a subject and converts a received optical signal into an electrical signal. The camera 5 can capture a still image, a moving image, or both through the electrical signal from the imaging element. In the example illustrated in FIG. 1, the camera 5 is disposed on the same side of the mobile device 1 as the display 3.

The display 3 is disposed on the upper surface side of the mobile device 1. The display 3 includes a display screen such as a liquid crystal display or an organic electroluminescence (EL) display. The light-emitting module 10 is disposed on the same side of the mobile device 1 as the display 3, that is, on the upper surface side of the mobile device 1. As illustrated in FIG. 1, the light-emitting module 10 is disposed on the same side of the mobile device 1 as the display 3 in a top view. For example, the light-emitting module 10 may be disposed inward of the contour of the display 3 in a top view. Alternatively, the light-emitting module 10 may be disposed outward of the contour of the display 3 in a top view, for example, in a region adjacent to the contour of the display 3.

The display 3 includes a light-transmissive cover plate 3G that protects members disposed inside the housing 2, such as a backlight or a light deflecting member. In the example illustrated in FIG. 1, the light-emitting module 10 is disposed at a position overlapping the cover plate 3G. That is, the cover plate 3G covers the light-emitting module 10. However, the light-emitting module 10 may be exposed through the cover plate 3G. For example, the cover plate 3G may have an opening, and the light-emitting module 10 may be disposed at a position overlapping the opening in a top view.

The light-emitting module 10 emits light toward, for example, a user of the mobile device 1. The light-emitting module 10 may be configured to continuously emit light for a given period of time. Further, the light-emitting module 10 may be used as a light-emitting module for a flash that emits light to a subject to be photographed by the camera 5, for example. In this case, the light-emitting module 10 is preferably disposed alongside the camera 5 as illustrated in FIG. 1. Further, the light-emitting module 10 may be used as a flashlight (torch light) of the mobile device 1 at night or in a dark place.

### Light-Emitting Module 10

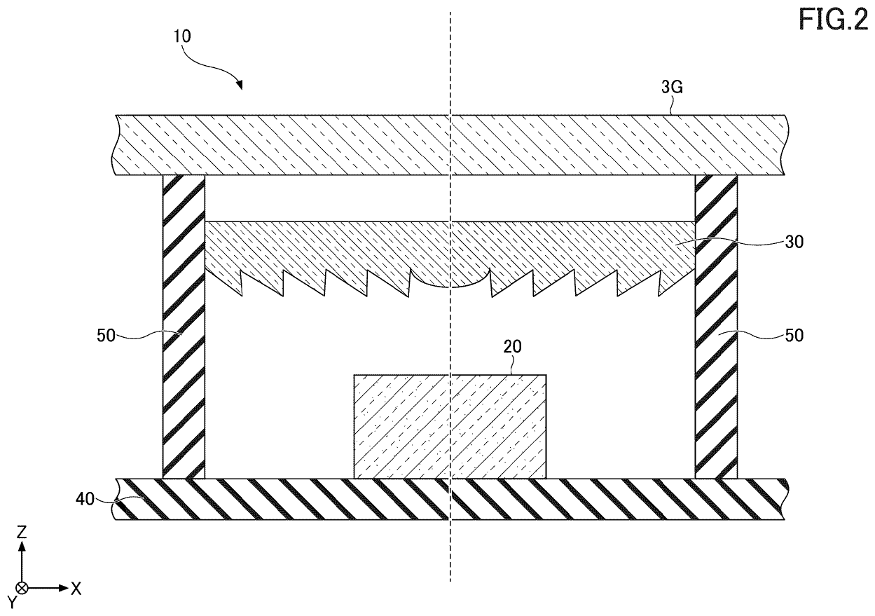

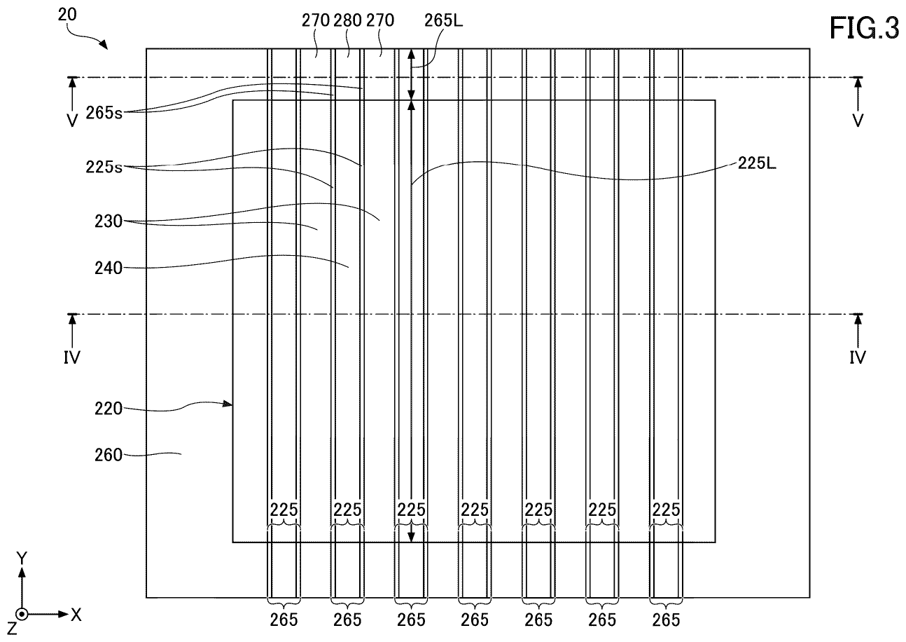

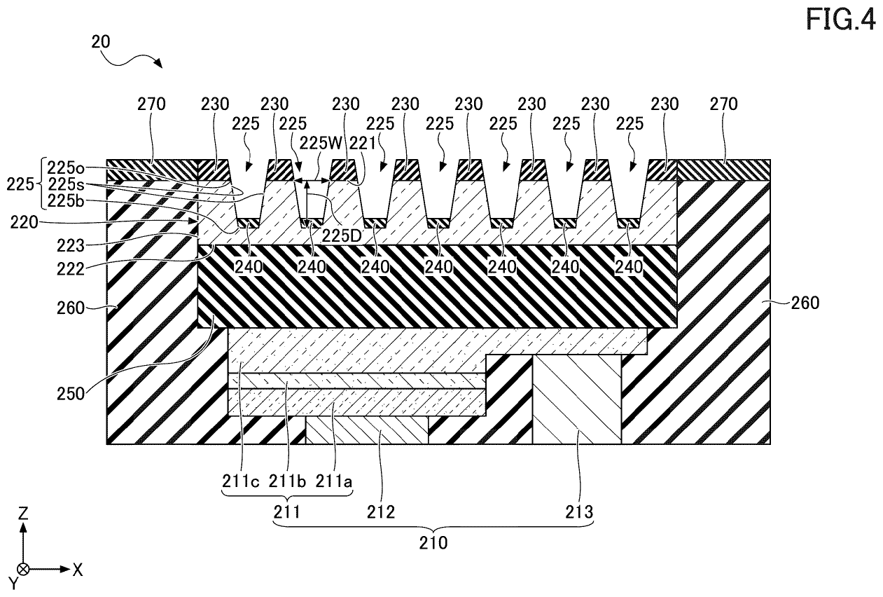

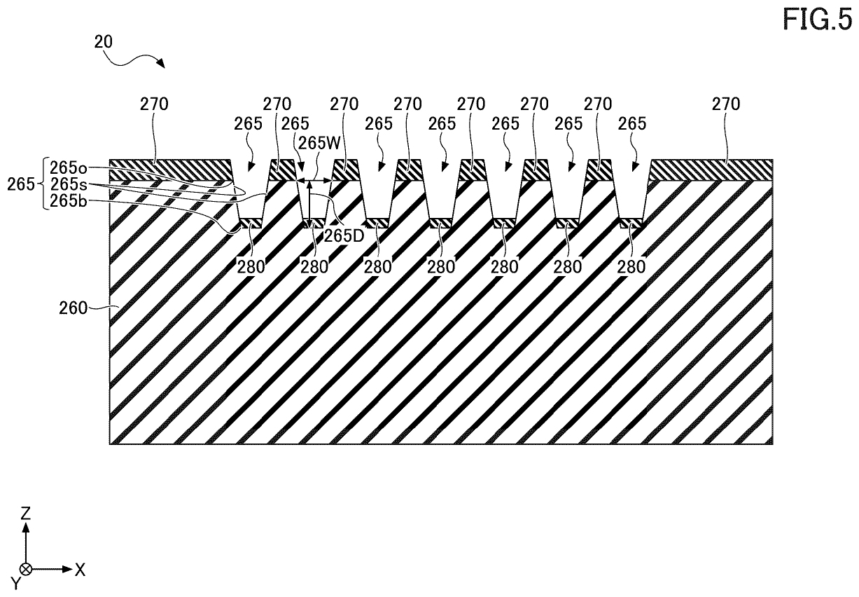

Subsequently, an example of the light-emitting module 10 according to the embodiment will be described with reference to FIG. 2 to FIG. 5. FIG. 2 is a cross-sectional view schematically illustrating the light-emitting module 10 taken along line II-II of FIG. 1. FIG. 3 is a top view schematically illustrating a light-emitting device 20 included in the light-emitting module 10. FIG. 4 is a cross-sectional view schematically illustrating the light-emitting device 20 taken along line IV-IV of FIG. 3. FIG. 5 is a cross-sectional view schematically illustrating the light-emitting device 20 taken along line V-V of FIG. 3.

As illustrated in FIG. 2, the light-emitting module 10 includes the light-emitting device 20 and a lens 30. The light-emitting device 20 and the lens 30 are disposed so as to be separated from each other in the Z-axis direction. In the example illustrated in FIG. 2, the light-emitting module 10 includes one light-emitting device 20, but the light-emitting module 10 may include two or more light-emitting devices 20. The light-emitting module 10 may further include other components such as a substrate 40 or a lens support 50.

### Light-Emitting Device 20

An example of a configuration of the light-emitting device 20 will be described. As illustrated in FIG. 3 to FIG. 5, the light-emitting device 20 includes a light-emitting element 210, a light-transmissive member 220, and a first light-shielding member 230. The light-emitting device 20 may further include other components such as a second light-shielding member 240, a wavelength conversion member 250, a covering member 260, a third light-shielding member 270, and a fourth light-shielding member 280.

The light-emitting device 20 has, for example, a substantially rectangular shape in a top view. However, the shape of the light-emitting device 20 in a top view is not limited to a substantially rectangular shape. The shape of the light-emitting device 20 in a top view may be a substantially circular shape, a substantially elliptical shape, or a substantially polygonal shape other than a rectangular shape.

The length of the light-emitting device 20 in the X-axis direction is, for example, 300 μm or more and 3,000 μm or less. The length of the light-emitting device 20 in the Y-axis direction is, for example, 300 μm or more and 3,000 μm or less. The length of the light-emitting device 20 in the Z-axis direction is, for example, 150 μm or more and 700 μm or less. However, the lengths of the light-emitting device 20 in the X-axis direction, the Y-axis direction, and the Z-axis direction are not limited thereto. In the example illustrated in FIG. 3, the outer edge of the light-emitting device 20 coincides with the outer edge of the covering member 260 in a top view. However, the outer edge of the light-emitting device 20 may coincide with the outer edge of a member other than the covering member 260 in a top view.

### Light-Emitting Element 210

An example of a configuration of the light-emitting element 210 will be described. The light-emitting element 210 has, for example, a substantially rectangular shape in a top view. However, the shape of the light-emitting element 210 in a top view is not limited to a substantially rectangular shape. The shape of the light-emitting element 210 in a top view may be a substantially circular shape, a substantially elliptical shape, or a substantially polygonal shape other than a rectangular shape.

The length of the light-emitting element 210 in the X-axis direction is, for example, 100 μm or more and 1,500 μm or less. The length of the light-emitting element 210 in the Y-axis direction is, for example, 100 μm or more and 1,500 μm or less. The length of the light-emitting element 210 in the Z-axis direction is, for example, 100 μm or more and 500 μm or less. However, the lengths of the light-emitting element 210 in the X-axis direction, the Y-axis direction, and the Z-axis direction are not limited thereto. The outer edge of the light-emitting element 210 is located inward of the outer edge of the light-emitting device 20 in a top view.

As illustrated in FIG. 4, the light-emitting element 210 includes a semiconductor structure 211, a first electrode 212, and a second electrode 213. The light-emitting element 210 may further include other components such as an element substrate disposed on the semiconductor structure 211. The element substrate may be a light-transmissive member composed of sapphire or the like. As used herein, the term “light-transmissive” means having a transmittance of 60% or more and preferably 80% or more with respect to light. However, a transmittance of 60% or more is not necessarily required for light of all wavelengths.

The semiconductor structure 211 includes a first semiconductor layer 211a, a light-emitting layer 211b, and a second semiconductor layer 211c. As illustrated in FIG. 4, the first semiconductor layer 211a, the light-emitting layer 211b, and the second semiconductor layer 211c are layered in this order in the Z-axis direction. One of the first semiconductor layer 211a and the second semiconductor layer 211c is formed of an n-side semiconductor. The other of the first semiconductor layer 211a and the second semiconductor layer 211c is formed of a p-side semiconductor. The light-emitting layer 211b may have a single quantum well (SQW) structure, or may have a multiple quantum well (MQW) structure including a plurality of well layers.

The semiconductor structure 211 includes a plurality of semiconductor layers formed of nitride semiconductors. Examples of the nitride semiconductors include semiconductors of all compositions obtained by varying the composition ratios x and y within their ranges in the chemical formula InₓAl_{y}Ga_{1-x-y}N (0≤x, 0≤y, x+y≤1). The peak emission wavelength of light emitted from the light-emitting layer 211b can be appropriately selected according to the purpose. The light-emitting layer 211b is configured to emit, for example, visible light or ultraviolet light. In the present embodiment, the peak emission wavelength of the light emitted from the light-emitting layer 211b is preferably 400 nm or more and 530 nm or less, more preferably 420 nm or more and 490 nm or less, and even more preferably 440 nm or more and 460 nm or less. The light-emitting layer 211b emits, for example, blue light. However, the peak emission wavelength of the light emitted from the light-emitting layer 211b is not limited thereto. The semiconductor forming each of the first semiconductor layer 211a, the light-emitting layer 211b, and the second semiconductor layer 211c is not limited to the nitride semiconductor.

The semiconductor structure 211 may include a plurality of light-emitting parts each including the first semiconductor layer 211a, the light-emitting layer 211b, and the second semiconductor layer 211c. If the semiconductor structure 211 includes a plurality of light-emitting parts, the plurality of light-emitting parts may each include well layers having different peak emission wavelengths or well layers having the same peak emission wavelength. The “same peak emission wavelength” may include a variation of about several nanometers. A combination of peak emission wavelengths of light from the plurality of light-emitting parts can be appropriately selected. For example, if the semiconductor structure 211 includes two light-emitting parts, combinations of lights emitted from the light-emitting parts include blue light and blue light, green light and green light, red light and red light, ultraviolet light and ultraviolet light, blue light and green light, blue light and red light, blue light and ultraviolet light, green light and red light, and the like. For example, if the semiconductor structure 211 includes three light-emitting parts, combinations of light emitted from the light-emitting parts include blue light, green light, and red light. Each of the light-emitting parts may include one or more well layers emitting light having different peak emission wavelengths from other well layers. The light emitted from the light-emitting layer 211b may be referred to as “light emitted from the light-emitting element 210” or “light exiting from the light-emitting element 210.”

The first electrode 212 and the second electrode 213 are positive and negative electrodes for allowing a current to flow through the semiconductor structure 211. As illustrated in FIG. 4, the first electrode 212 and the second electrode 213 are disposed on the lower surface of the semiconductor structure 211 and arranged at positions separated from each other. The first electrode 212 is connected to the first semiconductor layer 211a of the semiconductor structure 211. The second electrode 213 is connected to the second semiconductor layer 211c of the semiconductor structure 211.

Examples of a material used for each of the first electrode 212 and the second electrode 213 include elemental metals such as gold, silver, aluminum, nickel, rhodium, copper, titanium, platinum, palladium, molybdenum, chromium, and tungsten, or alloy materials containing these metals. However, the material used for each of the first electrode 212 and the second electrode 213 is not limited thereto. Each of the first electrode 212 and the second electrode 213 may have a single-layer structure formed of a single metal material or alloy material, or may have a layered structure in which a plurality of metal materials or alloy materials are layered in the Z-axis direction.

### Light-Transmissive Member 220

An example of a configuration of the light-transmissive member 220 will be described. The light-transmissive member 220 has, for example, a substantially rectangular shape in a top view. However, the shape of the light-transmissive member 220 in a top view is not limited to a substantially rectangular shape. The shape of the light-transmissive member 220 in a top view may be a substantially circular shape, a substantially elliptical shape, or a substantially polygonal shape other than a rectangular shape.

The length of the light-transmissive member 220 in the X-axis direction is, for example, 100 μm or more and 3,000 μm or less. The length of the light-transmissive member 220 in the Y-axis direction is, for example, 100 μm or more and 3,000 μm or less. The length of the light-transmissive member 220 in the Z-axis direction is, for example, 30 μm or more and 200 μm or less. However, the lengths of the light-transmissive member 220 in the X-axis direction, the Y-axis direction, and the Z-axis direction are not limited thereto. In the example illustrated in FIG. 3, the outer edge of the light-transmissive member 220 is located between the outer edge of the light-emitting element 210 and the outer edge of the covering member 260 (light-emitting device 20) in a top view. However, the outer edge of the light-transmissive member 220 may coincide with the outer edge of the light-emitting element 210 or the outer edge of the covering member 260 (light-emitting device 20) in a top view.

The light-transmissive member 220 is disposed on the light-emitting element 210. The light-transmissive member 220 includes, as a main component, a light-transmissive material, such as glass, a ceramic, sapphire, a silicone resin, a modified silicone resin, an epoxy resin, a modified epoxy resin, an acrylic resin, a phenol resin, or a fluorine resin. The light-transmissive member 220 transmits light emitted from the light-emitting element 210 and allows the light to exit to the outside.

The light-transmissive member 220 includes a filler having a light scattering property. Examples of the filler include metal oxide particles such as titanium oxide, aluminum oxide, zirconium oxide, zinc oxide, magnesium oxide, gallium oxide, tantalum oxide, niobium oxide, bismuth oxide, yttrium oxide, iridium oxide, indium oxide, tin oxide, or tungsten oxide. Light incident on the light-transmissive member 220 is scattered by the filler, for example. The light-transmissive member 220 may include a filler other than metal oxide particles, such as silicon oxide or boron nitride.

As illustrated in FIG. 4, the light-transmissive member 220 has upper surface(s) 221, a lower surface 222, and lateral surfaces 223 between the upper surface(s) 221 and the lower surface 222. Further, the light-transmissive member 220 has a first recessed portion 225 that opens at the upper surface 221. For example, the first recessed portion 225 is a recessed portion recessed from an opening 2250 located at the upper surface 221 of the light-transmissive member 220 toward the-Z side. The first recessed portion 225 has lateral surfaces 225s and a bottom portion 225b. The upper ends of the lateral surfaces 225s of the first recessed portion 225 are coplanar with the upper surface 221 of the light-transmissive member 220.

The first light-shielding member 230 is located on the upper surface 221 of the light-transmissive member 220. Further, the second light-shielding member 240 is located on the bottom portion 225b of the first recessed portion 225. In contrast, neither the first light-shielding member 230 nor the second light-shielding member 240 is located on the lateral surfaces 225s of the first recessed portion 225. That is, the lateral surfaces 225s of the first recessed portion 225 of the light-transmissive member 220 are exposed from the first light-shielding member 230 and the second light-shielding member 240. With this configuration, light emitted from the light-emitting element 210 and incident on the light-transmissive member 220 can be extracted to the outside through the lateral surfaces 225s of the first recessed portion 225. However, in a case where the second light-shielding member 240 is not provided, light can also be extracted from the bottom portion 225b of the first recessed portion 225.

The light-transmissive member 220 preferably has a plurality of first recessed portions 225. The light-transmissive member 220 having the plurality of first recessed portions 225 can increase the area of lateral surfaces 225s of the plurality of first recessed portions 225. That is, a region of the light-transmissive member 220 exposed from the first light-shielding member 230 and the second light-shielding member 240 can be increased. Accordingly, the light extraction efficiency of the light-emitting device 20 can be improved. However, the light-transmissive member 220 may have at least one first recessed portion 225.

As illustrated in FIG. 3, the first recessed portion 225 preferably has a linear shape in a top view. The first recessed portion 225 having a geometrically simple shape such as a linear shape in a top view allows light to be extracted from the lateral surfaces 225s of the first recessed portion 225 regardless of the position of the first recessed portion 225. In addition, the first recessed portion 225 having a linear shape in a top view can reduce the possibility that the light-emitting device 20 is easily visually recognized from the outside. Further, the first recessed portion 225 having a linear shape in a top view allows the exposed lateral surfaces 225s of the first recessed portion 225 of the light-transmissive member 220 to be less noticeable from the outside. As a result, the exposed lateral surfaces 225s of the first recessed portion 225 of the light-transmissive member 220 are less likely to be visually recognized from the outside. That is, the light-emitting device 20 is less likely to be visually recognized from the outside. However, the shape of the first recessed portion 225 in a top view is not limited to a linear shape. The shape of the first recessed portion 225 in a top view may be a shape different from a linear shape, such as a curved shape, a meandering shape, a rectangular shape, a circular shape, or an elliptical shape. In the example illustrated in FIG. 3, the first recessed portion 225 extends in the Y-axis direction, but the first recessed portion 225 may extend in a direction different from the Y-axis direction.

A length 225L in the elongated direction of the first recessed portion 225 (hereinafter referred to as the length 225L of the first recessed portion 225) is preferably equal to the length of the light-transmissive member 220 in a direction (the Y-axis direction in FIG. 3) parallel to the elongated direction of the first recessed portion 225. This can increase the area of the lateral surfaces 225s of the first recessed portion 225. As a result, the light extraction efficiency of the light-emitting device 20 can be further improved. However, the length 225L of the first recessed portion 225 may be smaller than the length of the light-transmissive member 220 in the direction parallel to the elongated direction of the first recessed portion 225.

A width 225W of the first recessed portion 225 (that is, the opening width of the first recessed portion 225 at the upper surface of the light-transmissive member 220) is, for example, 20 μm or more and 500 μm or less. As used herein, the “width 225W of the first recessed portion 225” refers to a length in a direction orthogonal to the elongated direction of the first recessed portion 225 in a top view. Further, the ratio of the area of the first recessed portion(s) 225 (that is, the length 225L of the first recessed portion 225×the width(s) 225W of the first recessed portion(s) 225) to the area of the upper surface 221 of the light-transmissive member 220 in a top view of the light-emitting device 20 is preferably 30% or more and 60% or less. Further, a depth 225D of the first recessed portion 225 is smaller than the thickness of the light-transmissive member 220 (that is, the length of the light-transmissive member 220 in the Z-axis direction). That is, the first recessed portion 225 does not extend through the light-transmissive member 220 in the Z-axis direction. The depth 225D of the first recessed portion 225 is, for example, 50% or more and 90% or less of the thickness of the light-transmissive member 220. As used herein, the “depth 225D of the first recessed portion 225” refers to a length from the opening 225o at the upper end of a lateral surface 225s to the bottom portion 225b of the first recessed portion 225 in the Z-axis direction.

In a case where the light-transmissive member 220 has a plurality of first recessed portions 225, the plurality of first recessed portions 225 are preferably arranged in a stripe pattern in a top view. That is, it is preferable that the plurality of first recessed portions 225 extend in the same direction. In this case, intervals between adjacent first recessed portions 225 of the plurality of first recessed portions 225 may be the same or may be different. Arranging the plurality of first recessed portions 225 in a stripe pattern in a top view makes the light-emitting device 20 less likely to be visually recognized from the outside while ensuring the light extraction efficiency of the light-emitting device 20.

In the example illustrated in FIG. 3, all of the plurality of first recessed portions 225 are elongated in one direction, that is, in the Y-axis direction in a top view. However, the elongated direction of the plurality of first recessed portions 225 is not limited to one direction. For example, some of the plurality of first recessed portions 225 may be elongated in a first direction (for example, the Y-axis direction), and the other first recessed portions 225 may be elongated in a second direction (for example, the X-axis direction). In this case, the plurality of first recessed portions 225 are arranged in a lattice pattern such that the first recessed portions 225 elongated in the first direction and the first recessed portions 225 elongated in the second direction intersect each other in a top view. In addition, some other first recessed portions 225 may be elongated in a direction different from the first direction and the second direction.

The first recessed portion 225 is defined by the lateral surfaces 225s, which are continuous with the opening 225o (that is, continuous with the upper surface 221 of the light-transmissive member 220), and the bottom portion 225b. The first recessed portion 225 has at least two lateral surfaces 225s opposing each other in a cross-sectional view. As illustrated in FIG. 4, each of the two lateral surfaces 225s opposing each other is continuous with the bottom portion 225b. As illustrated in FIG. 4, the bottom portion 225b may be parallel to the X-axis direction in a cross-sectional view. Further, the bottom portion 225b may be parallel to the Y-axis direction in a cross-sectional view. Further, the bottom portion 225b may be a bottom surface parallel to the X-axis and the Y-axis. The bottom portion 225b may be inclined with respect to the X-axis direction and/or the Y-axis direction in a cross-sectional view.

Each of the two lateral surfaces 225s opposing each other is preferably an inclined surface inclined from the opening 225o toward the bottom portion 225b of the first recessed portion 225. Further, each of the two lateral surfaces 225s opposing each other is preferably an inclined surface that is inclined such that the width 225W of the first recessed portion 225 decreases from the opening 225o toward the bottom portion 225b. This can increase the area of the lateral surface 225s of the first recessed portion 225 in a top view. As a result, the light extraction efficiency of the light-emitting device 20 can be improved. The “area of the lateral surface 225s of the first recessed portion 225 in a top view” refers to the area of the lateral surface 225s of the first recessed portion 225 on an XY plane when the lateral surfaces 225s of the first recessed portion 225 are projected onto the XY plane. The same applies to the “area of any other member or surface in a top view.”

Each of the lateral surfaces 225s may be an inclined surface that is inclined such that the width 225W of the first recessed portion 225 increases from the opening 225o toward the bottom portion 225b. Each of the two lateral surfaces 225s may be provided so as to be orthogonal to the upper surface 221 of the light-transmissive member 220 in a cross-sectional view.

### First Light-Shielding Member 230

An example of a configuration of the first light-shielding member 230 will be described. The first light-shielding member 230 shields, for example, light reaching the light-emitting device 20 from the outside. The first light-shielding member 230 has a property of absorbing, for example, 70% or more of visible light.

The first light-shielding member 230 is located on the upper surface 221 of the light-transmissive member 220. The first light-shielding member 230 does not close the opening of the first recessed portion 225. That is, the first recessed portion 225 is exposed from the first light-shielding member 230 at the upper surface of the light-emitting device 20. The first light-shielding member 230 located on the upper surface 221 of the light-transmissive member 220 can reduce the amount of light reflected by the upper surface of the light-emitting device 20 and/or inside the light-emitting device 20 after reaching the light-emitting device 20 from the outside. This makes the light-emitting device 20 less likely to be visually recognized from the outside.

From the viewpoint of making the light-emitting device 20 less likely to be visually recognized from the outside, it is preferable that the first light-shielding member 230 is located on the entire upper surface 221 of the light-transmissive member 220. However, the upper surface 221 of the light-transmissive member 220 may have a region where the first light-shielding member 230 is not located, within a range that does not impair the effect of making the light-emitting device 20 less likely to be visually recognized from the outside. The thickness of the first light-shielding member 230 is, for example, 0.1 μm or more and 20 μm or less. The “thickness of the first light-shielding member 230” refers to the length of the first light-shielding member 230 in the Z-axis direction.

The first light-shielding member 230 preferably includes a black filler. Examples of the black filler include reduced metal oxide particles (hereinafter referred to as “reduced oxide particles”) such as titanium (III) oxide (Ti₂O₃); and carbon particles such as activated carbon, graphite, or carbon black. If the light-transmissive member 220 includes metal oxide particles, the black filler of the first light-shielding member 230 preferably includes reduced oxide particles including the same metal element as a metal element included in the metal oxide particles of the light-transmissive member 220. The reduced oxide particles include not only metal oxide particles, such as Ti₂O₃, generated by an oxygen vacancy, but also metal oxide particles, such as TiOxN₂₋ₓ, in which some oxygen atoms are substituted by other atoms such as nitrogen atoms. In the present specification, the term “black” means a color that absorbs 70% or more of visible light. In other words, the term “black” in the present specification includes not only black, but also colors similar to black, such as dark gray or dark brown.

The concentration of the black filler included in the first light-shielding member 230 is preferably higher than the concentration of the filler included in the light-transmissive member 220. When the concentration of the black filler included in the first light-shielding member 230 is higher than the concentration of the filler included in the light-transmissive member 220, the property of the first light-shielding member 230 to absorb visible light can be further improved. This can further make the light-emitting device 20 less likely to be visually recognized from the outside.

In the present embodiment, for example, a black portion formed on the upper surface 221 of the light-transmissive member 220 by irradiation with laser light can be used as the first light-shielding member 230. In this case, the first light-shielding member 230 includes a portion corresponding to an upper surface of the light-transmissive member 220 before the irradiation with the laser light. The upper surface 221 of the light-transmissive member 220 illustrated in FIG. 4 is a region that is located inside the light-transmissive member 220 before the irradiation with the laser light and becomes a boundary between the light-transmissive member 220 and the first light-shielding member 230 after the irradiation with the laser light. That is, the first light-shielding member 230 may be physically monolithic with the light-transmissive member 220. In this case, a clear boundary may be present between the first light-shielding member 230 and the light-transmissive member 220, but does not have to be present. In the present embodiment, a clear boundary between the first light-shielding member 230 and the light-transmissive member 220 is not necessarily required. The first light-shielding member 230 may be a member different from the light-transmissive member 220. For example, the first light-shielding member 230 may be a black resin layer or the like that is different from the light-transmissive member 220.

### Second Light-Shielding Member 240

An example of a configuration of the second light-shielding member 240 will be described. The second light-shielding member 240 shields, for example, light reaching the light-emitting device 20 from the outside. The second light-shielding member 240 has a property of absorbing, for example, 70% or more of visible light.

The second light-shielding member 240 is located on the bottom portion 225b of the first recessed portion 225. The second light-shielding member 240 located on the bottom portion 225b of the first recessed portion 225 can further reduce the amount of light reflected by the upper surface of the light-emitting device 20 and/or inside the light-emitting device 20 after reaching the light-emitting device 20 from the outside. This can make the light-emitting device 20 less likely to be visually recognized from the outside.

From the viewpoint of making the light-emitting device 20 less likely to be visually recognized from the outside, it is preferable that the second light-shielding member 240 is located on the entire bottom portion 225b of the first recessed portion 225. However, the bottom portion 225b of the first recessed portion 225 may have a region where the second light-shielding member 240 is not located, within a range that does not impair the effect of making the light-emitting device 20 less likely to be visually recognized from the outside. The thickness of the second light-shielding member 240 is, for example, 0.1 μm or more and 20 μm or less. The “thickness of the second light-shielding member 240” refers to the length of the second light-shielding member 240 in the Z-axis direction. The thickness of the second light-shielding member 240 may be the same as or different from the thickness of the first light-shielding member 230. For example, the thickness of the second light-shielding member 240, located on the bottom portion of the first recessed portion 225 where light from the outside is less likely to reach, can be made smaller than the thickness of the first light-shielding member 230 that is easily visually recognized from the outside. With this configuration, the area of the exposed lateral surfaces 225s of the first recessed portion 225 of the light-transmissive member 220 can be increased, and thus the light extraction efficiency of the light-emitting device 20 can be improved.

The second light-shielding member 240 preferably includes a black filler. The black filler included in the second light-shielding member 240 may be the same as or similar to the black filler included in the first light-shielding member 230. If the light-transmissive member 220 includes metal oxide particles, the black filler of the second light-shielding member 240 preferably includes reduced oxide particles including the same metal element as a metal element included in the metal oxide particles of the light-transmissive member 220.

The concentration of the black filler included in the second light-shielding member 240 is preferably higher than the concentration of the filler included in the light-transmissive member 220. When the concentration of the black filler included in the second light-shielding member 240 is higher than the concentration of the filler included in the light-transmissive member 220, the property of the second light-shielding member 240 to absorb visible light can be further improved. This can further make the light-emitting device 20 less likely to be visually recognized from the outside.

In the present embodiment, for example, a black portion formed on the bottom portion 225b of the first recessed portion 225 by irradiation with laser light can be used as the second light-shielding member 240. In this case, the second light-shielding member 240 includes a portion corresponding to the bottom portion of the first recessed portion 225 before the irradiation with the laser light. The bottom portion 225b of the first recessed portion 225 illustrated in FIG. 4 is a region that is located inside the light-transmissive member 220, that is, on the −Z side of the light-transmissive member 220 relative to the first recessed portion 225 before the irradiation with the laser light and becomes a boundary between the light-transmissive member 220 and the second light-shielding member 240 within the first recessed portion 225 after the irradiation with the laser light. That is, the second light-shielding member 240 may be physically monolithic with the bottom portion 225b of the first recessed portion 225. In this case, a clear boundary may be present between the second light-shielding member 240 and the light-transmissive member 220, but does not have to be present. In the present embodiment, a clear boundary between the second light-shielding member 240 and the light-transmissive member 220 is not necessarily required. The second light-shielding member 240 may be a member different from the light-transmissive member 220. For example, the second light-shielding member 240 may be a black resin layer or the like that is different from the light-transmissive member 220.

### Wavelength Conversion Member 250

An example of a configuration of the wavelength conversion member 250 will be described. The wavelength conversion member 250 has, for example, a substantially rectangular shape in a top view. However, the shape of the wavelength conversion member 250 in a top view is not limited to a substantially rectangular shape. The shape of the wavelength conversion member 250 in a top view may be a substantially circular shape, a substantially elliptical shape, or a substantially polygonal shape other than a rectangular shape.

The length of the wavelength conversion member 250 in the X-axis direction is, for example, 100 μm or more and 3,000 μm or less. The length of the wavelength conversion member 250 in the Y-axis direction is, for example, 100 μm or more and 3,000 μm or less. The length of the wavelength conversion member 250 in the Z-axis direction is, for example, 30 μm or more and 200 μm or less. However, the lengths of the wavelength conversion member 250 in the X-axis direction, the Y-axis direction, and the Z-axis direction are not limited thereto. The outer edge of the wavelength conversion member 250 coincides with the outer edge of the light-transmissive member 220 in a top view. The outer edge of the wavelength conversion member 250 may coincide with the outer edge of the light-emitting element 210 in a top view or may coincide with the outer edge of the light-emitting device 20 in a top view. Further, the outer edge of the wavelength conversion member 250 may be located between the outer edge of the light-transmissive member 220 and the outer edge of the light-emitting element 210 or between the outer edge of the light-transmissive member 220 and the outer edge of the light-emitting device 20.

As illustrated in FIG. 4, the wavelength conversion member 250 is disposed between the light-emitting element 210 and the light-transmissive member 220 in the Z-axis direction. The wavelength conversion member 250 can convert the wavelength of at least a portion of light emitted from the light-emitting element 210, thereby emitting light having a different wavelength. That is, of light emitted from the light-emitting element 210, the wavelength conversion member 250 can emit both light whose wavelength is converted by the wavelength conversion member 250 and light transmitted through the wavelength conversion member 250 without having its wavelength converted by the wavelength conversion member 250. Mixed-color light thereof is emitted from the upper surface of the wavelength conversion member 250. The wavelength conversion member 250 may convert the wavelength of substantially the entire light emitted from the light-emitting element 210. In this case, the light emitted from the upper surface of the wavelength conversion member 250 is substantially only wavelength-converted light.

The wavelength conversion member 250 includes a light-transmissive base and a phosphor. Examples of the light-transmissive base included in the wavelength conversion member 250 include ceramics such as aluminum nitride, aluminum oxide, yttrium oxide, or yttrium aluminum perovskite (YAP); inorganic materials such as glass or sapphire; and organic materials such as a resin including one or more of a silicone resin, a modified silicone resin, an epoxy resin, a modified epoxy resin, an acrylic resin, a phenol resin, or a fluororesin, and a hybrid resin thereof. The phosphor included in the wavelength conversion member 250 may be included inside the light-transmissive base, or may be provided in a layer on the upper surface or the lower surface of the light transmissive base formed in a plate shape.

Examples of the phosphor included in the wavelength conversion member 250 include yttrium aluminum garnet based phosphors (for example, (Y,Gd)₃(Al,Ga)₅O₁₂:Ce), lutetium aluminum garnet based phosphors (for example, Lu₃(Al,Ga)₅O₁₂:Ce), terbium aluminum garnet based phosphors (for example, Tb₃(Al,Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆Cl₂:Eu), silicate based phosphors (for example, (Ba,Sr,Ca,Mg)₂SiO₄:Eu), oxynitride based phosphors such as β-SiAlON based phosphors (for example, (Si,Al)₃(O,N)₄:Eu) or α-SiAlON based phosphors (for example, Ca(Si,Al)₁₂(O,N)₁₆:Eu), nitride based phosphors such as LSN based phosphors (for example, (La,Y)₃Si₆N₁₁:Ce), BSESN based phosphors (for example, (Ba,Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca)AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5 MgO·0.5 MgF₂·GeO₂:Mn), quantum dots having a Perovskite structure (for example, (Cs,FA,MA)(Pb,Sn)(F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu)(In,Ga)(S,Se)₂).

As illustrated in FIG. 4, the wavelength conversion member 250 is preferably separated from the first recessed portion 225. Specifically, the upper surface of the wavelength conversion member 250 is preferably separated from the bottom portion 225b of the first recessed portion 225. When the wavelength conversion member 250 is separated from the first recessed portion 225, light emitted from the upper surface of the wavelength conversion member 250 is easily extracted to the outside through the light-transmissive member 220. In addition, projections and recesses conforming to the first recessed portion 225 are less likely to be generated on the upper surface of the wavelength conversion member 250. This can reduce variations in the thickness of the wavelength conversion member 250. As a result, variations in chromaticity of light emitted from the wavelength conversion member 250 can be reduced.

### Covering Member 260

An example of a configuration of the covering member 260 will be described. The light-emitting device 20 includes the covering member 260 that covers at least the lateral surfaces of the light-emitting element 210. The covering member 260 may cover the lateral surfaces of the wavelength conversion member 250, and may further cover the lateral surfaces 223 of the light-transmissive member 220. A portion of the covering member 260 may be located on the upper surface of the light-emitting device 20. In the example illustrated in FIG. 3, the covering member 260 is disposed in a frame shape so as to surround the light-transmissive member 220 and the first light-shielding member 230 in a top view. The covering member 260 has a substantially rectangular shape in a top view. However, the shape of the covering member 260 in a top view is not limited to a substantially rectangular shape. The shape of the covering member 260 in a top view may be a substantially circular shape, a substantially elliptical shape, or a substantially polygonal shape other than a rectangular shape.

In a case where the light-emitting device 20 includes the covering member 260 in the upper surface thereof, the length in the X-axis direction of the covering member 260 on the upper surface of the light-emitting device 20 is, for example, 150 μm or more and 1,550 μm or less. The length of the covering member 260 in the Y-axis direction is, for example, 150 μm or more and 1,550 μm or less. The length of the covering member 260 in the Z-axis direction is, for example, 150 μm or more and 700 μm or less. However, the lengths of the covering member 260 in the X-axis direction, in the Y-axis direction, and in the Z-axis direction are not limited thereto. The outer edge of the covering member 260 coincides with the outer edge of the light-emitting device 20 in a top view. However, the outer edge of the covering member 260 may be located at any other position.

The covering member 260 preferably has a high light shielding property. Examples of the light shielding property include a property of blocking light, a property of absorbing light, and a property of reflecting light (hereinafter referred to as “light reflectivity”). Among them, the covering member 260 preferably has light reflectivity. For example, the covering member 260 preferably has a reflectance of 60% or more, and more preferably has a reflectance of 70% or more, 80% or more, or 90% or more with respect to light emitted from the light-emitting element 210.

The covering member 260 includes, for example, a filler having light reflectivity and an insulating base. Examples of the filler included in the covering member 260 include metal oxide particles such as titanium oxide, zirconium oxide, or aluminum oxide. The filler included in the covering member 260 may be particles composed of a substance different from a metal oxide, such as boron nitride. The insulating base may be composed of an organic material, may be composed of an inorganic material, or may be composed of both an organic material and an inorganic material. As an example of the organic material, a resin such as a silicone resin can be used. As an example of the inorganic material, an alkali metal silicate can be used.

In the example illustrated in FIG. 4, the covering member 260 covers the lateral surfaces of the light-emitting element 210 and the lateral surfaces 223 of the light-transmissive member 220. The upper surface of the covering member 260 and the upper surface 221 of the light-transmissive member 220 are coplanar with each other. When the covering member 260 covers the lateral surfaces of the light-emitting element 210 and the lateral surfaces 223 of the light-transmissive member 220, light emitted from the lateral surfaces of the light-emitting element 210 and light emitted from the lateral surfaces of the light-transmissive member 220 can be reflected toward the lateral surfaces 225s of the first recessed portion 225. Accordingly, the light extraction efficiency of the light-emitting device 20 can be improved.

As illustrated in FIG. 3 and FIG. 5, the covering member 260 preferably has a second recessed portion 265 that opens at the upper surface of the covering member 260. For example, the second recessed portion 265 is recessed from an opening 265o located at the upper surface of the covering member 260 toward the-Z side. The second recessed portion 265 has lateral surfaces 265s and a bottom portion 265b. The upper ends of the lateral surfaces 265s of the second recessed portion 265 are coplanar with the upper surface of the covering member 260.

As illustrated in FIG. 3, the second recessed portion 265 preferably has a linear shape in a top view. Further, the second recessed portion 265 and the first recessed portion 225 are preferably located on the same straight line in a top view. When the second recessed portion 265 and the first recessed portion 225 are located on the same straight line in a top view, light emitted from the lateral surfaces 225s of the first recessed portion 225 and directed toward the covering member 260 can be extracted to the outside through the second recessed portion 265. Accordingly, the light extraction efficiency of the light-emitting device 20 can be improved. Further, when the second recessed portion 265 and the first recessed portion 225 are located on the same straight line in a top view, the possibility that the light-emitting device 20 is easily visually recognized from the outside can be reduced.

In the example illustrated in FIG. 3, the second recessed portion 265 extends in the Y-axis direction. However, the direction in which the second recessed portion 265 extends is not limited to the Y-axis direction. Further, in the example illustrated in FIG. 3, second recessed portions 265 are located in a region on the +Y side and a region on the −Y side of the covering member 260 relative to the light-transmissive member 220. However, the second recessed portions 265 may be located in a region on the +X side and a region on the −X side of the covering member 260 relative to the light-transmissive member 220. Alternatively, the second recessed portions 265 may be located in a region on the +X side, a region on the −X side, a region on the +Y side, and a region on the −Y side of the covering member 260 relative to the light-transmissive member 220.

The covering member 260 preferably has a plurality of second recessed portions 265. Similar to the plurality of first recessed portions 225, the plurality of second recessed portions 265 are preferably arranged in a stripe pattern in a top view. Similar to the plurality of first recessed portions 225, arranging the plurality of second recessed portions 265 in a stripe pattern in a top view can make the light-emitting device 20 less likely to be visually recognized from the outside.

A length 265L in the elongated direction of the second recessed portion 265 (hereinafter referred to as the length 265L of the second recessed portion 265) is preferably equal to the length of the covering member 260 in a direction parallel to the elongated direction of the second recessed portion 265. The second recessed portion 265 may extend to the outer edge of the covering member 260, but does not have to reach the outer edge of the covering member 260.

A width 265W of the second recessed portion 265 (that is, the opening width of the second recessed portion 265 at the upper surface of the covering member 260) may be the same as or different from the width 225W of the first recessed portion 225. The width 265W of the second recessed portion 265 is, for example, 20 μm or more and 500 μm or less. As used herein, the “width 265W of the second recessed portion 265” refers to a length in a direction orthogonal to the elongated direction of the second recessed portion 265 in a top view. Further, the ratio of the area of the second recessed portion(s) 265 (that is, the length 265L of the second recessed portion 265×the width(s) 265W of the second recessed portion(s) 265) to the area of the upper surface of the covering member 260 in a top view of the light-emitting device 20 is preferably 30% or more and 60% or less.

A depth 265D of the second recessed portion 265 is, for example, 20 μm or more and 180 μm or less. The depth 265D of the second recessed portion 265 may be the same as or different from the depth 225D of the first recessed portion 225. As used herein, the “depth 265D of the second recessed portion 265” refers to a length from the opening 265o at the upper end of a lateral surface 265s to the bottom portion 265b of the second recessed portion 265 in the Z-axis direction.

The second recessed portion 265 is defined by the lateral surfaces 265s, which are continuous with the opening 265o, and the bottom portion 265b. The second recessed portion 265 has at least two lateral surfaces 265s opposing each other in a cross-sectional view. As illustrated in FIG. 5, each of the two lateral surfaces 265s opposing each other is continuous with the bottom portion 265b. As illustrated in FIG. 5, the bottom portion 265b may be parallel to the X-axis direction in a cross-sectional view. Further, the bottom portion 265b may be parallel to the Y-axis direction in a cross-sectional view. Further, the bottom portion 265b may be a bottom surface parallel to the X-axis and the Y-axis. The bottom portion 265b may be inclined with respect to the X-axis direction and/or the Y-axis direction in a cross-sectional view.

Each of the two lateral surfaces 265s may be an inclined surface inclined from the opening 265o toward the bottom portion 265b of the second recessed portion 265. Specifically, each of the lateral surfaces 265s may be an inclined surface that is inclined such that the width 265W of the second recessed portion 265 decreases from the opening 265o toward the bottom portion 265b, or may be an inclined surface that is inclined such that the width 265W of the second recessed portion 265 increases from the opening 265o toward the bottom portion 265b. Alternatively, each of the two lateral surfaces 265s may be provided so as to be orthogonal to the upper surface of the covering member 260 in a cross-sectional view.

### Third Light-Shielding Member 270

An example of a configuration of the third light-shielding member 270 will be described. The third light-shielding member 270 shields, for example, light reaching the light-emitting device 20 from the outside. The third light-shielding member 270 has a property of absorbing, for example, 70% or more of visible light.

The third light-shielding member 270 is located on the upper surface of the covering member 260. The third light-shielding member 270 located on the upper surface of the covering member 260 can further reduce the amount of light reflected by the upper surface of the light-emitting device 20 and/or inside the light-emitting device 20 after reaching the light-emitting device 20 from the outside. This can further make the light-emitting device 20 less likely to be visually recognized from the outside.

From the viewpoint of making the light-emitting device 20 less likely to be visually recognized from the outside, it is preferable that the third light-shielding member 270 is located on the entire upper surface of the covering member 260. However, the upper surface of the covering member 260 may have a region where the third light-shielding member 270 is not located, within a range that does not impair the effect of making the light-emitting device 20 less likely to be visually recognized from the outside. The thickness of the third light-shielding member 270 is, for example, 0.1 μm or more and 20 μm or less. The “thickness of the third light-shielding member 270” refers to the length of the third light-shielding member 270 in the Z-axis direction. The thickness of the third light-shielding member 270 may be the same as or different from the thickness of the first light-shielding member 230.

The third light-shielding member 270 preferably includes a black filler. The black filler included in the third light-shielding member 270 may be the same as or similar to the black filler included in at least one of the first light-shielding member 230 or the second light-shielding member 240. If the covering member 260 includes metal oxide particles, the black filler of the third light-shielding member 270 preferably includes reduced oxide particles including the same metal element as a metal element included in the metal oxide particles of the covering member 260.

The concentration of the black filler included in the third light-shielding member 270 is preferably higher than the concentration of the filler included in the covering member 260. When the concentration of the black filler included in the third light-shielding member 270 is higher than the concentration of the filler included in the covering member 260, the property of the third light-shielding member 270 to absorb visible light can be further improved. This can further make the light-emitting device 20 less likely to be visually recognized from the outside.

In the present embodiment, for example, a black portion formed on the upper surface of the covering member 260 by irradiation with laser light can be used as the third light-shielding member 270. In this case, the third light-shielding member 270 includes a portion corresponding to the upper surface of the covering member 260 before the irradiation with the laser light. The upper surface of the covering member 260 illustrated in FIG. 5 is a region that is located inside the covering member 260 before the irradiation with the laser light and becomes a boundary between the covering member 260 and the third light-shielding member 270 after the irradiation with the laser light. That is, the third light-shielding member 270 may be physically monolithic with the covering member 260. In this case, a clear boundary may be present between the third light-shielding member 270 and the covering member 260, but does not have to be present. In the present embodiment, a clear boundary between the third light-shielding member 270 and the covering member 260 is not necessarily required. The third light-shielding member 270 may be a member different from the covering member 260. For example, the third light-shielding member 270 may be a black resin layer or the like that is different from the covering member 260.

### Fourth Light-Shielding Member 280

An example of a configuration of the fourth light-shielding member 280 will be described. The fourth light-shielding member 280 shields, for example, light reaching the light-emitting device 20 from the outside. The fourth light-shielding member 280 has a property of absorbing, for example, 70% or more of visible light.

The fourth light-shielding member 280 is located on the bottom portion 265b of the second recessed portion 265. The fourth light-shielding member 280 located on the bottom portion 265b of the second recessed portion 265 can reduce the amount of light reflected by the upper surface of the light-emitting device 20 and/or inside the light-emitting device 20 after reaching the light-emitting device 20 from the outside. This can further make the light-emitting device 20 less likely to be visually recognized from the outside.

From the viewpoint of making the light-emitting device 20 less likely to be visually recognized from the outside, it is preferable that the fourth light-shielding member 280 is located on the entire bottom portion 265b of the second recessed portion 265. However, the bottom portion 265b of the second recessed portion 265 may have a region where the fourth light-shielding member 280 is not located, within a range that does not impair the effect of making the light-emitting device 20 less likely to be visually recognized from the outside. The thickness of the fourth light-shielding member 280 is, for example, 5 μm or more and 20 μm or less. The “thickness of the fourth light-shielding member 280” refers to the length of the fourth light-shielding member 280 in the Z-axis direction. The thickness of the fourth light-shielding member 280 may be the same as or different from the thickness of the second light-shielding member 240.

The fourth light-shielding member 280 preferably includes a black filler. The black filler included in the fourth light-shielding member 280 may be the same as or similar to the black filler included in at least one of the first light-shielding member 230, the second light-shielding member 240, or the third light-shielding member 270. If the covering member 260 includes metal oxide particles, the black filler of the fourth light-shielding member 280 preferably includes reduced oxide particles including the same metal element as a metal element included in the metal oxide particles of the covering member 260.

The concentration of the black filler included in the fourth light-shielding member 280 is preferably higher than the concentration of the filler included in the covering member 260. When the concentration of the black filler included in the fourth light-shielding member 280 is higher than the concentration of the filler included in the covering member 260, the property of the fourth light-shielding member 280 to absorb visible light can be improved. This can further make the light-emitting device 20 less likely to be visually recognized from the outside.

In the present embodiment, for example, a black portion formed on the bottom portion 265b of the second recessed portion 265 by irradiation with laser light can be used as the fourth light-shielding member 280. In this case, the fourth light-shielding member 280 includes a portion corresponding to the bottom portion of the second recessed portion 265 before the irradiation with the laser light. The bottom portion 265b of the second recessed portion 265 illustrated in FIG. 5 is a region that is located inside the covering member 260, that is, on the −Z side of the covering member 260 relative to the second recessed portion 265 before the irradiation with the laser light and becomes a boundary between the covering member 260 and the fourth light-shielding member 280 within the second recessed portion 265 after the irradiation with the laser light. That is, the fourth light-shielding member 280 may be physically monolithic with the covering member 260 within the second recessed portion 265. In this case, a clear boundary may be present between the fourth light-shielding member 280 and the covering member 260, but does not have to be present. In the present embodiment, a clear boundary between the fourth light-shielding member 280 and the covering member 260 is not necessarily required. The fourth light-shielding member 280 may be a member different from the covering member 260. For example, the fourth light-shielding member 280 may be a black resin layer or the like that is different from the covering member 260.

### Lens 30

An example of a configuration of the lens 30 will be described. The lens 30 is disposed above the light-emitting device 20. Light extracted from the upper surface of the light-emitting device 20 is transmitted through the lens 30 and then exits to the outside. Examples of a material constituting the lens 30 include light-transmissive materials such as a polycarbonate resin, an acrylic resin, a silicone resin, or glass. However, the material constituting the lens 30 may be a light-transmissive material other than the above.

As illustrated in FIG. 2, a Fresnel lens can be used as the lens 30. The lens 30 has a plurality of annular projecting portions on a light incident surface corresponding to the lower surface of the lens 30. The plurality of projecting portions are arranged concentrically in a top view. In addition, the lens 30 has a flat light-emitting surface corresponding to the upper surface of the lens 30. However, the lens 30 may be a lens other than the Fresnel lens. For example, the lens 30 may be a plano-convex lens or a biconvex lens.

### Substrate 40

An example of a configuration of the substrate 40 will be described. The substrate 40 includes, for example, an insulating base and wiring. Examples of a material constituting the base include a polyimide resin, a polyester resin, a glass epoxy, a BT resin, aluminum nitride, silicon nitride, and aluminum oxide. The substrate 40 can include, as the wiring, upper surface wiring disposed on the upper surface of the base, lower surface wiring disposed on the lower surface of the base, and inner layer wiring that connects the upper surface wiring and the lower surface wiring and is disposed inside the base. The upper surface wiring is electrically connected to the first electrode 212 and the second electrode 213 of the light-emitting element 210 of the light-emitting device 20. With this configuration, the light-emitting element 210 is electrically connected to an external power source via the lower surface wiring, the inner layer wiring, and the like of the substrate 40. The light-emitting module 10 may further include, on the substrate 40, an electronic circuit such as large-scale integration (LSI) that controls the light emitting operation of the light-emitting element 210.

The substrate 40 has an upper surface, a lower surface, and a lateral surface between the upper surface and the lower surface. The substrate 40 has a substantially circular shape in a top view. However, the shape of the substrate 40 in a top view is not limited to a substantially circular shape. The shape of the substrate 40 in a top view may be a substantially rectangular shape, a substantially elliptical shape, a substantially polygonal shape, or any other shape.

The light-emitting device 20 is mounted on the upper surface of the substrate 40. It is preferable that at least the upper surface of the substrate 40 has a black appearance. When at least the upper surface of the substrate 40 has a black appearance, reflection of light reaching the upper surface of the substrate 40 is reduced. Accordingly, the inside of the light-emitting module 10 is less likely to be visually recognized from the outside.

### Lens Support 50

An example of a configuration of the lens support 50 will be described. The lens support 50 supports the lens 30. The lens support 50 is disposed outward of the light-emitting device 20 in a top view. The lens support 50 preferably has a black appearance. The lens support 50 having a black appearance can absorb light reaching the light-emitting module 10. As a result, the amount of light reaching the light-emitting device 20 can be reduced. This can further make the light-emitting device 20 less likely to be visually recognized from the outside.

The lens support 50 is, for example, a cylindrical-shaped member having an internal space in which the light-emitting device 20 and the lens 30 are housed. However, the lens support 50 may have a shape other than the cylindrical shape, such as a rectangular tubular shape. The lens support 50 is bonded to the upper surface of the substrate 40 via a bonding member such as a publicly-known adhesive.

### Method of Manufacturing Light-Emitting Device 20

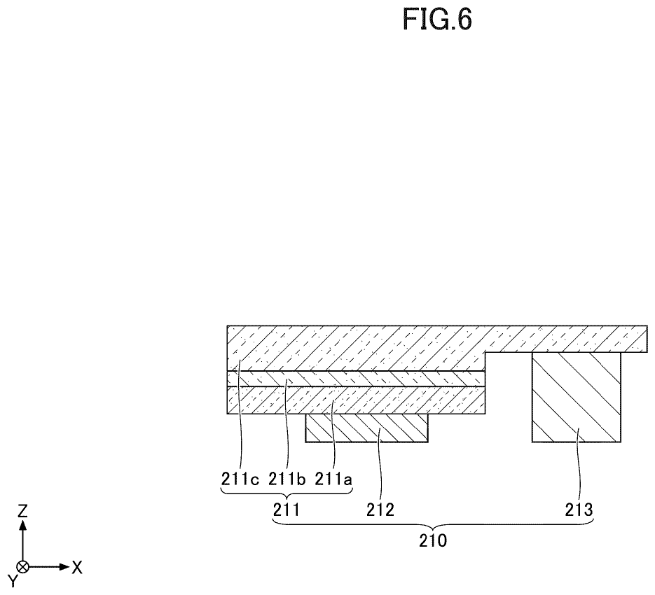

Subsequently, an example of a method of manufacturing the light-emitting device 20 will be described with reference to FIG. 6 to FIG. 10. FIG. 6 to FIG. 10 are schematic cross-sectional views illustrating the example of the method of manufacturing the light-emitting device 20. The method of manufacturing the light-emitting device 20 includes a step of providing a light-emitting element 210, a step of disposing a light-transmissive member 220, a step of forming a first recessed portion 225, and a step of forming a first light-shielding member 230. The method of manufacturing the light-emitting device 20 may include other steps such as a step of disposing a wavelength conversion member 250.

As illustrated in FIG. 6, the step of providing the light-emitting element 210 is performed. For example, a first semiconductor layer 211a, a light-emitting layer 211b, and a second semiconductor layer 211c are formed by using an element substrate such as sapphire as a growth substrate. Examples of a method of forming the first semiconductor layer 211a, the light-emitting layer 211b, and the second semiconductor layer 211c include a metal-organic chemical vapor deposition (MOCVD) method. A semiconductor structure 211 is obtained by such a manufacturing method. After the semiconductor structure 211 is formed, a first electrode 212 and a second electrode 213 are formed on the lower surface of the semiconductor structure 211 by using a deposition method such as a sputtering method. As a result, the light-emitting element 210 is obtained. The element substrate used to form the semiconductor structure 211 may be removed after the first electrode 212 and the second electrode 213 are formed, but does not have to be removed.

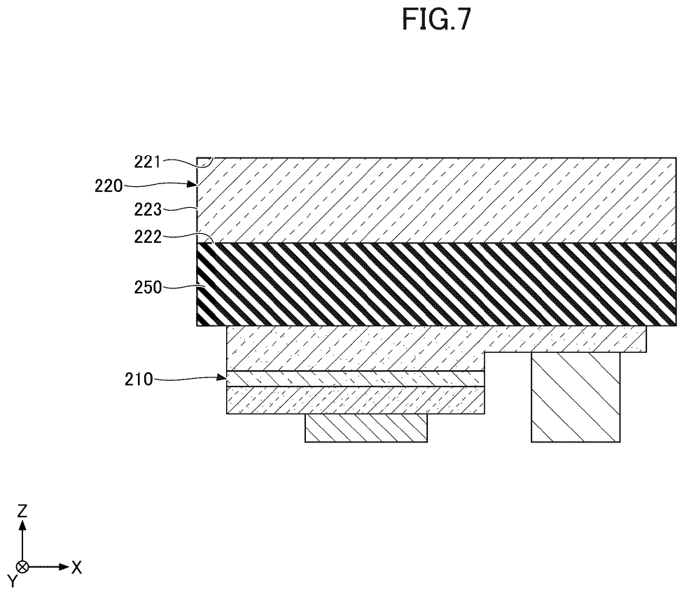

Subsequently, as illustrated in FIG. 7, the step of disposing the light-transmissive member 220 on the light-emitting element 210 is performed. For example, the light-transmissive member 220 is disposed on the light-emitting element 210 with a bonding member such as an adhesive resin interposed therebetween or without a bonding member interposed therebetween. If a bonding member is not used, a direct bonding method such as pressure bonding, surface activation bonding, atomic diffusion bonding, or hydroxyl group bonding can be used to dispose the light-transmissive member 220 on the light-emitting element 210. As illustrated in FIG. 7, a wavelength conversion member 250 may be disposed between the light-emitting element 210 and the light-transmissive member 220.

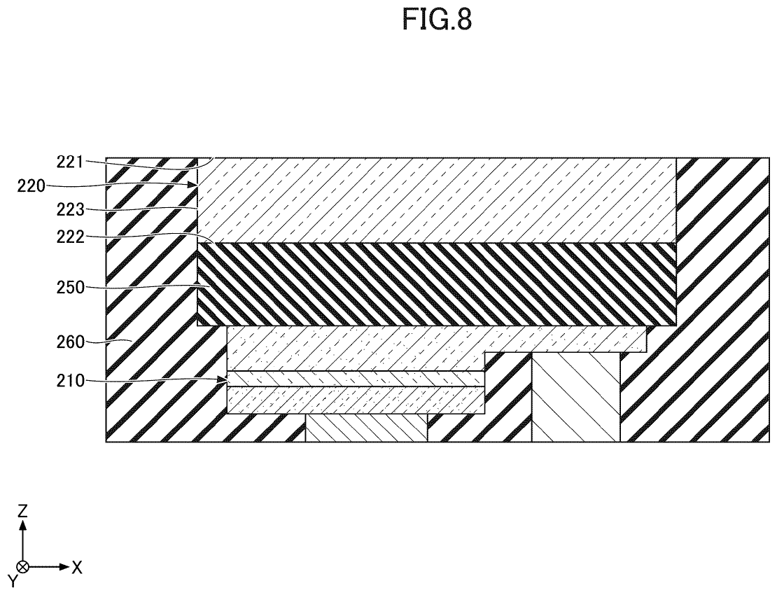

After the light-transmissive member 220 is disposed on the light-emitting element 210, the covering member 260 may be disposed as illustrated in FIG. 8. Specifically, the covering member 260 is disposed so as to cover at least the lateral surfaces of the light-emitting element 210. The covering member 260 may be disposed so as to cover the lateral surfaces 223 of the light-transmissive member 220 and the lateral surfaces of the wavelength conversion member 250. Alternatively, the covering member 260 may cover the lateral surfaces of the light-emitting element 210 before the light-transmissive member 220 is disposed on the light-emitting element 210. In this case, the light-transmissive member 220 covers the upper surface of the light-emitting element 210 and the upper surface of the covering member 260. In a case where the light-emitting device 20 includes the wavelength conversion member 250 between the light-emitting element 210 and the light-transmissive member 220, the light-transmissive member 220 can cover the upper surface of the wavelength conversion member 250 and the upper surface of the covering member 260.

The covering member 260 can be disposed by a publicly-known method such as potting, spraying, printing, molding using a mold such as injection molding, compression molding, or transfer molding. For example, an uncured resin is potted in a region where the covering member 260 is to be disposed. Thereafter, the uncured resin is cured by heat treatment or the like so as to form the covering member 260. In this manner, the covering member 260 can be disposed.

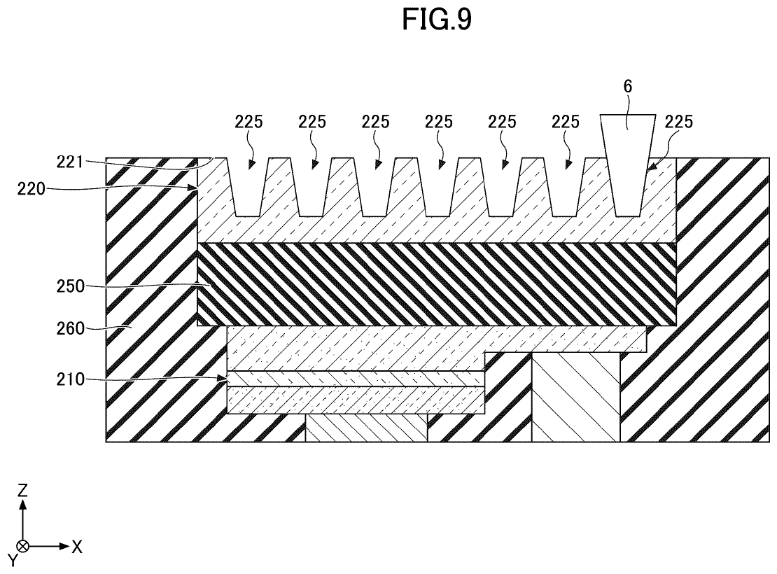

Subsequently, as illustrated in FIG. 9, the step of forming the first recessed portion 225 in the light-transmissive member 220 is performed. As an example, a cutting tool such as a blade 6 is used to form the first recessed portion 225 that opens at the upper surface 221 of the light-transmissive member 220. For example, the length 225L, the width 225W, and the depth 225D of the first recessed portion 225 and the shape of the first recessed portion 225 can be adjusted according to conditions such as the amount of movement of a cutting tool in each of the X-axis direction, the Y-axis direction, and the Z-axis direction and the cutting angle when the light-transmissive member 220 is cut from the upper surface 221, and the shape of the cutting tool. Further, a second recessed portion 265 that opens at the upper surface of the covering member 260 may be formed by using a cutting tool that is the same as or different from the cutting tool used to form the first recessed portion 225. The second recessed portion 265 may be formed at the same timing as or a different timing from the step of forming the first recessed portion 225.

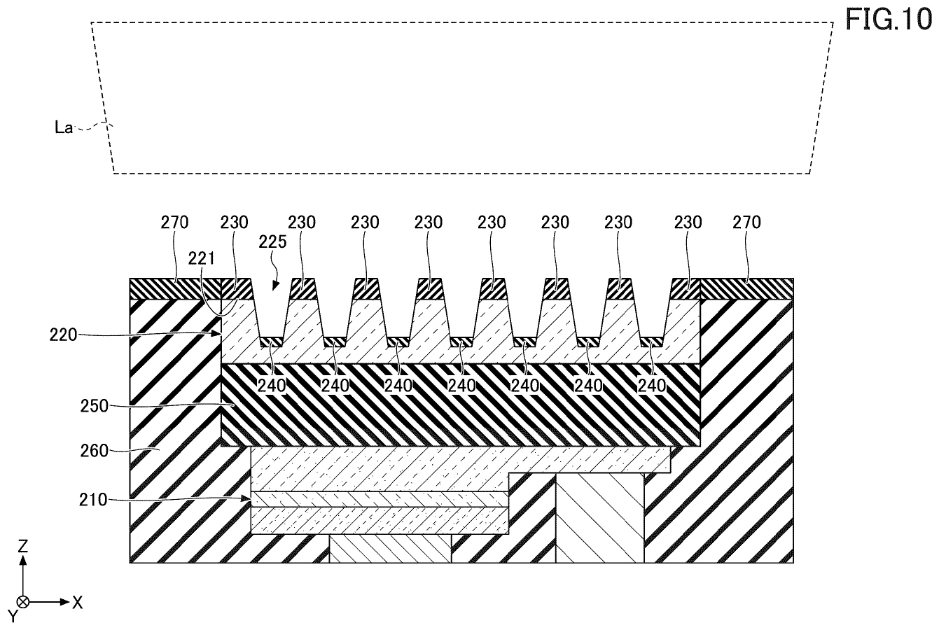

Subsequently, as illustrated in FIG. 10, the step of forming the first light-shielding member 230 is performed. As an example, the first light-shielding member 230 can be formed by irradiating the upper surface 221 of the light-transmissive member 220 with laser light La. In this case, it is assumed that the light-transmissive member 220 includes metal oxide particles as a filler. As illustrated in FIG. 10, the upper surface 221 of the light-transmissive member 220 irradiated with the laser light La turns black due to the light energy of the laser light La. Specifically, the filler located on the upper surface 221 side of the light-transmissive member 220 is changed into a black filler such as reduced oxide particles by the irradiation with the laser light La. That is, a region on the upper surface side of the light-transmissive member 220 including the black filler obtained by the irradiation with the laser light La becomes the first light-shielding member 230 located on the upper surface of the light-transmissive member 220. In this manner, the first light-shielding member 230 can be formed. As the laser light La, a gas laser or a solid-state laser can be used. As the gas laser, for example, an excimer laser can be used. In this example, the laser light La is an excimer laser, and for example, a krypton fluoride laser with a wavelength of 248 nm can be used. The spot diameter of the laser light La on the upper surface 221 of the light-transmissive member 220 is, for example, 5 μm or more and 10 μm or less. The intensity of the laser light La is, for example, 1 J/cm² or more and 2 J/cm² or less.

The thickness of the first light-shielding member 230 can be adjusted according to conditions such as the intensity of the laser light La or the number of shots of the laser light La. In the light-transmissive member 220 before the irradiation with the laser light La, the concentration of the filler is preferably set to be higher on the upper surface 221 side than on the lower surface 222 side. With this configuration, the concentration of the black filler included in the first light-shielding member 230 can be increased, and the property of the first light-shielding member 230 to absorb visible light can be further improved. As a result, the light-emitting device 20 is less likely to be visually recognized from the outside.

A nitrogen laser may be used as a laser for forming the first light-shielding member 230. By using the nitrogen laser, metal oxide particles (for example, TiO₂) included in the light-transmissive member 220 can be changed into a black filler such as reduced oxide particles including nitrogen atoms (for example, TiOₓN₂₋ₓ). However, the laser for forming the first light-shielding member 230 is not limited to the nitrogen laser.

A method of forming the first light-shielding member 230 is not limited to a method of irradiating the upper surface 221 of the light-transmissive member 220 with the laser light La. For example, the first light-shielding member 230 can be formed by disposing a resin layer or the like containing a black filler on the upper surface 221 of the light-transmissive member 220.

Other light-shielding members may be formed by using the same laser as or a different laser from the laser used to form the first light-shielding member 230. Specifically, a second light-shielding member 240 may be formed so as to be located on a bottom portion 225b of the first recessed portion 225, a third light-shielding member 270 may be formed so as to be located on the upper surface of the covering member 260, and a fourth light-shielding member 280 may be formed so as to be located on a bottom portion 265b of the second recessed portion 265. Each of the second light-shielding member 240, the third light-shielding member 270, and the fourth light-shielding member 280 may be formed at the same timing as or a different timing from the step of forming the first light-shielding member 230.

In this manner, the light-emitting device 20 is manufactured. In a case where a plurality of light-emitting devices 20 are manufactured at a time, a cutting method such as dicing is used to obtain the plurality of light-emitting devices 20. In addition, the upper surface and/or the lower surface of each member included in the light-emitting device 20 may be polished or ground as appropriate.

### First Modification

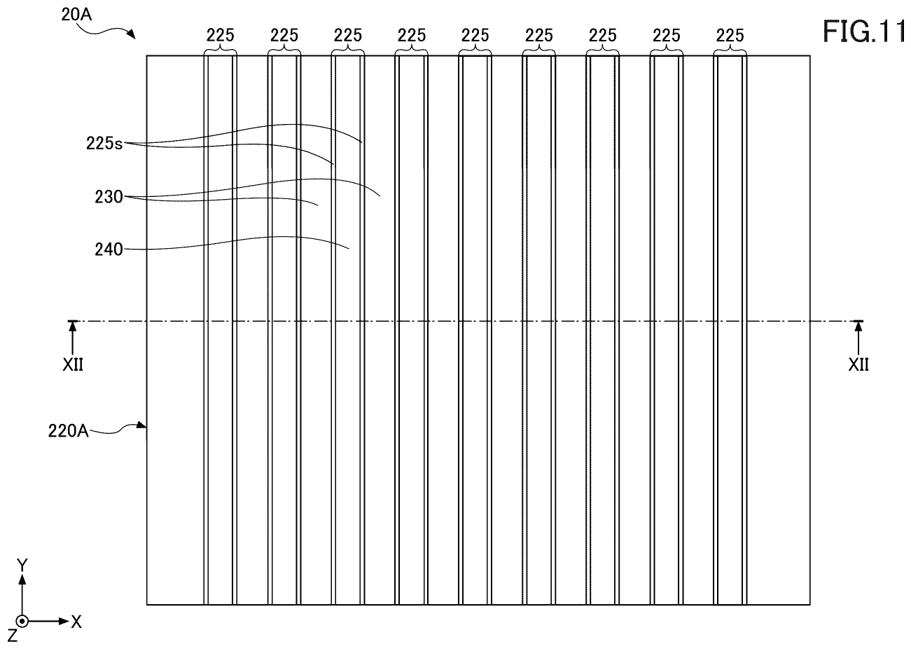

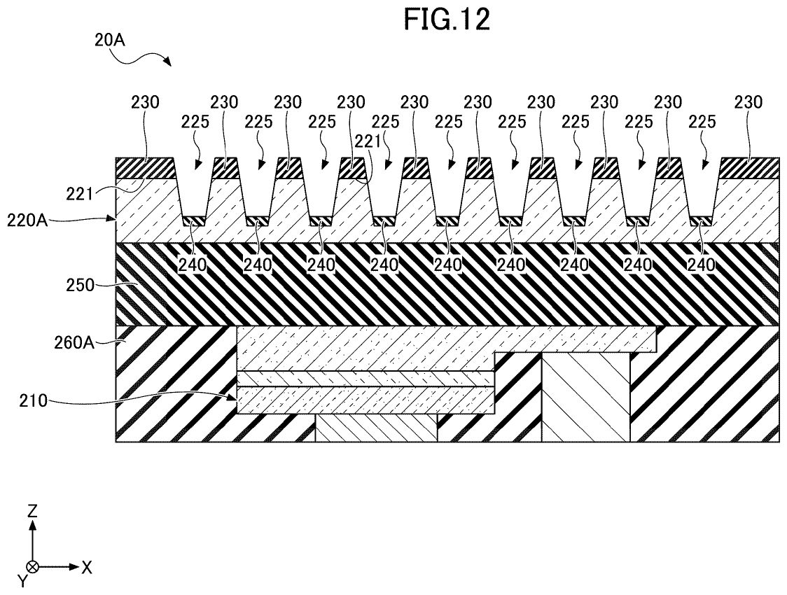

Subsequently, a light-emitting device 20A according to a first modification of the embodiment will be described with reference to FIG. 11 and FIG. 12. FIG. 11 is a top view schematically illustrating the light-emitting device 20A according to the first modification of the embodiment. FIG. 12 is a cross-sectional view schematically illustrating the light-emitting device 20A taken along line XII-XII of FIG. 11. In the first modification, the same components as those of the above-described embodiment are denoted by the same reference numerals, and the description thereof will be omitted as appropriate.

The light-emitting device 20A according to the first modification differs from the light-emitting device according to the embodiment mainly in a configuration of a light-transmissive member 220A and a configuration of a covering member 260A. Specifically, the lateral surfaces of the light-transmissive member 220A and the lateral surfaces of a wavelength conversion member 250 are exposed from the covering member 260A, and the lateral surfaces of a light-emitting element 210 is covered by the covering member 260A. The light-transmissive member 220A covers the upper surface of the covering member 260. In the example illustrated in FIG. 11, the outer edge of the light-transmissive member 220A coincides with the outer edge of the light-emitting device 20A in a top view. The second recessed portion 265, the third light-shielding member 270, and the fourth light-shielding member 280 of the light-emitting device 20 according to the embodiment are not provided in the light-emitting device 20A.

According to the light-emitting device 20A, the area of an upper surface 221 of the light-transmissive member 220A can be increased as compared to the light-transmissive member 220 of the light-emitting device 20 according to the embodiment. With this configuration, the area of a first light-shielding member 230 located on the upper surface 221 of the light-transmissive member 220A can be relatively increased, and the width 225W of a first recessed portion 225 and/or the number of first recessed portions 225 can be increased. This can make the light-emitting device 20A less likely to be visually recognized from the outside while ensuring the light extraction efficiency of the light-emitting device 20A.

### Second Modification

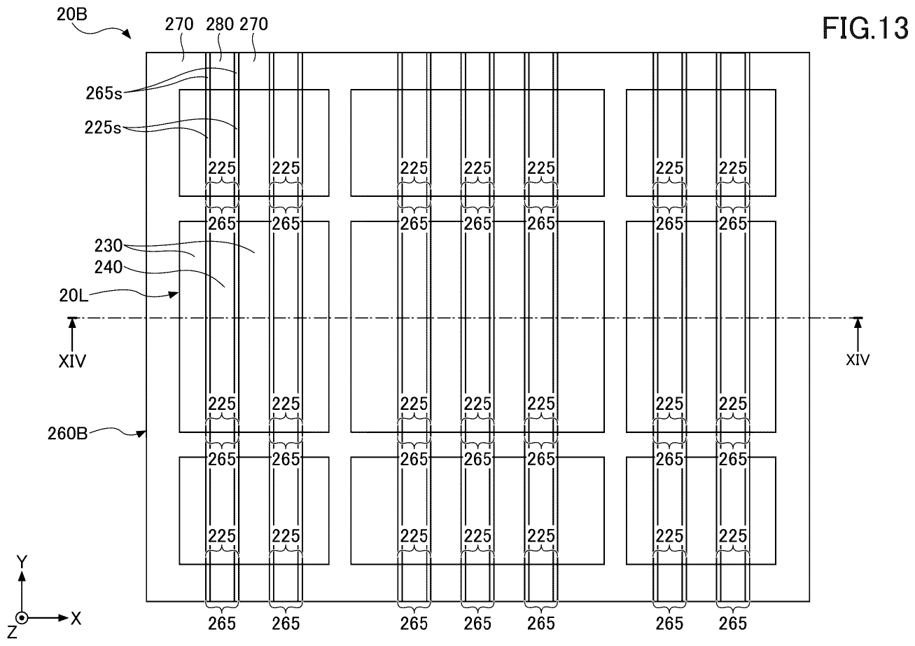

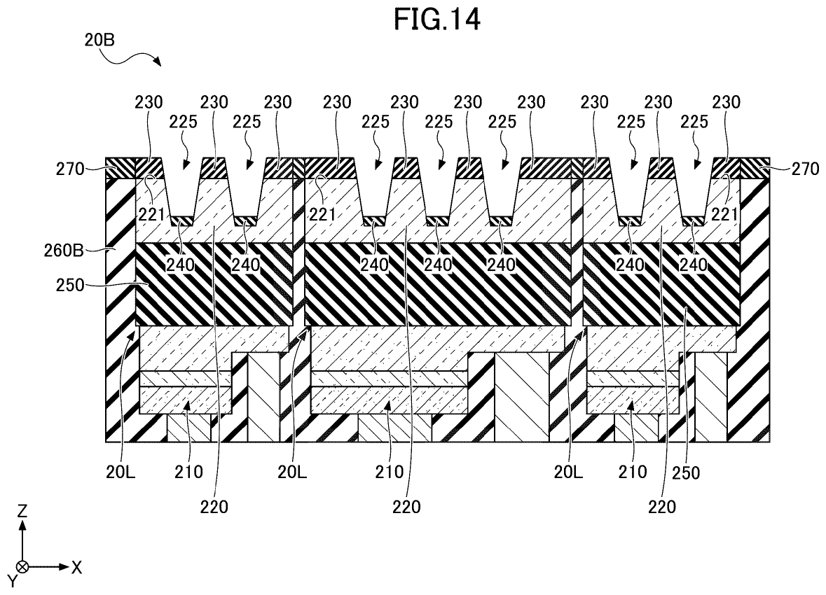

Subsequently, a light-emitting device 20B according to a second modification of the embodiment will be described with reference to FIG. 13 and FIG. 14. FIG. 13 is a top view schematically illustrating the light-emitting device 20B according to the second modification of the embodiment. FIG. 14 is a cross-sectional view schematically illustrating the light-emitting device 20B taken along line XIV-XIV of FIG. 13. In the second modification, the same components as those of the above-described embodiment and first modification are denoted by the same reference numerals, and the description thereof will be omitted as appropriate.

The light-emitting device 20B according to the second modification includes a plurality of light-emitting elements 210, a plurality of light-transmissive members 220, and a plurality of first light-shielding members 230. The plurality of light-transmissive members 220 are respectively arranged on the plurality of light-emitting elements 210. The plurality of first light-shielding members 230 are respectively located on upper surfaces 221 of the plurality of light-transmissive members 220.

In the example illustrated in FIG. 13 and FIG. 14, the light-emitting device 20B further includes a plurality of wavelength conversion members 250. The wavelength conversion member 250 is disposed between the light-emitting element 210 and the light-transmissive member 220 in each light-emitting structure 20L. A set of a light-emitting element 210, a wavelength conversion member 250, a light-transmissive member 220, and a first light-shielding member 230 is hereinafter referred to as a “light-emitting structure 20L.” That is, the light-emitting device 20B includes a plurality of light-emitting structures 20L. The light-emitting device 20B further includes a covering member 260B that collectively surrounds the plurality of light-emitting structure 20L in a top view.

In the example illustrated in FIG. 13, the light-emitting device 20B includes nine light-emitting structures 20L. However, the number of light-emitting structures 20L included in the light-emitting device 20B may be two or more. In the example illustrated in FIG. 13, the areas of the light-emitting structures 20L of the light-emitting device 20B in a top view are different. However, the areas of the light-emitting structures 20L in a top view may be the same. The number of first recessed portions 225 of a light-transmissive member 220 included in each of the light-emitting structures 20L may be one or more.

The plurality of light-emitting structures 20L are preferably electrically independent from each other. That is, in the light-emitting device 20B, each of the plurality of light-emitting structures 20L can preferably emit light individually. With this configuration, the light-emitting device 20B is less likely to be visually recognized from the outside, and a light emission timing and a light emission period of time can be controlled for each of the plurality of light-emitting structures 20L according to the user's operation, the external environment, and the like. Further, a third light-shielding member 270, including a black filler with a higher concentration than the concentration of a black filler included in the first light-shielding members 230, is disposed on the covering member 260B that is disposed between the plurality of light-emitting structures 20L. Thus, in a case where light emission timings of adjacent light-emitting structures 20L are different from each other, light propagation from a light-emitting structure 20L that emits light to a light-emitting structure 20L that does not emit light can be reduced. As a result, a luminance difference between the light-emitting structure 20L that emits light and the light-emitting structure 20L that does not emit light can be increased, and the light-emitting device can have a good contrast when the light is emitted individually.

Unlike the example illustrated in FIG. 13 and FIG. 14, one light-transmissive member 220 may be disposed on the plurality of light-emitting elements 210. In addition, the light-transmissive member 220 monolithically disposed over the plurality of light-emitting elements 210 may cover the upper surface of the covering member 260B.

### Third Modification

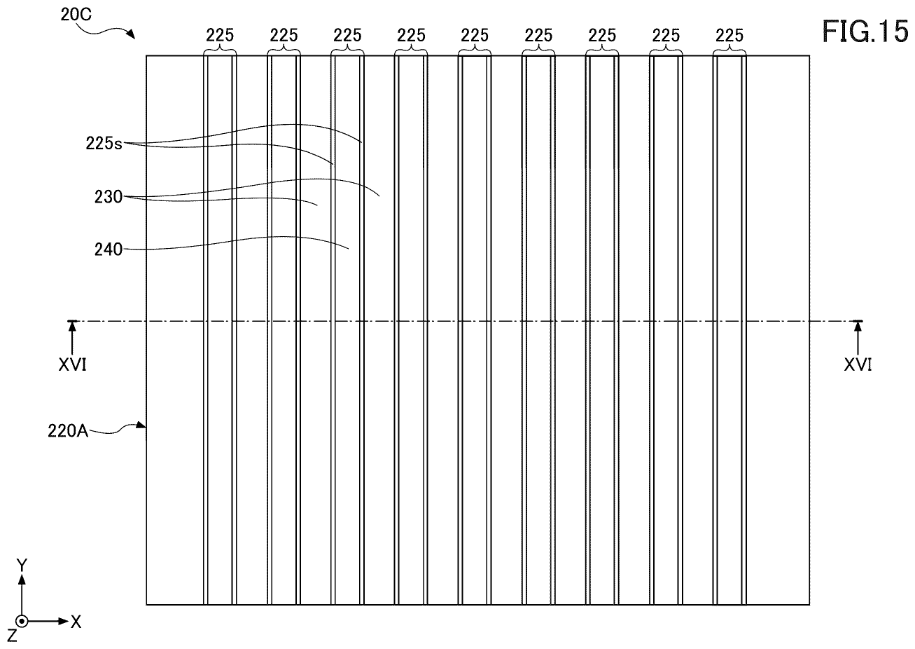

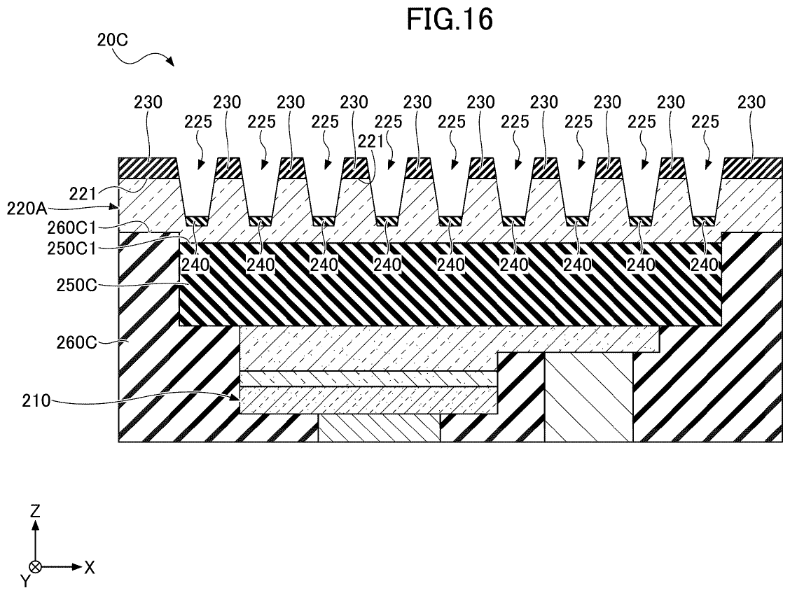

Subsequently, a light-emitting device 20C according to a third modification of the embodiment will be described with reference to FIG. 15 and FIG. 16. FIG. 15 is a top view schematically illustrating the light-emitting device 20C according to the third modification of the embodiment. FIG. 16 is a cross-sectional view schematically illustrating the light-emitting device 20C taken along line XVI-XVI of FIG. 15. In the third modification, the same components as those of the above-described embodiment, the first modification, and the second modification are denoted by the same reference numerals, and the description thereof will be omitted as appropriate.

The light-emitting device 20C according to the third modification differs from the light-emitting devices according to the embodiment, the first modification, and the second modification mainly in a configuration of a covering member 260C. Specifically, as illustrated in FIG. 16, the lateral surfaces of a light-transmissive member 220A are exposed from the covering member 260C, and the lateral surfaces of a light-emitting element 210 and the lateral surfaces of a wavelength conversion member 250C are covered by the covering member 260C. The light-transmissive member 220A covers an upper surface 260C1 of the covering member 260C. The covering member 260C covering the lateral surfaces of the light-emitting element 210 and the lateral surfaces of the wavelength conversion member 250C allows, of light emitted from the light-emitting element 210, light emitted from the lateral surfaces of the light-emitting element 210 and the lateral surfaces of the wavelength conversion member 250C to be reflected upward. Accordingly, the light extraction efficiency of the light-emitting device 20C can be improved.

Similar to the light-emitting device 20 according to the embodiment, according to the light-emitting device 20C, light emitted from the lateral surfaces of the light-emitting element 210 and the lateral surfaces of the wavelength conversion member 250C is less likely to be extracted from the lateral surfaces of the light-emitting device 20C. Accordingly, the light extraction efficiency from the upper surface of light-emitting device 20C can be improved. Further, according to the light-emitting device 20C, the light-transmissive member 220A covers the upper surface 260C1 of the covering member 260C. That is, the light-transmissive member 220A covers a boundary between the covering member 260C and the wavelength conversion member 250C. This can reduce peeling between the covering member 260C and the wavelength conversion member 250C, and reduce leakage of light from the boundary between the covering member 260C and the wavelength conversion member 250C. As a result, a highly reliable light-emitting device 20C can be obtained.

When the light-transmissive member 220A covers an upper surface 250C1 of the wavelength conversion member 250C and the upper surface 260C1 of the covering member 260C as in the light-emitting device 20C according to the third modification, the upper surface 250C1 of the wavelength conversion member 250C and the upper surface 260C1 of the covering member 260C may have the same height (that is, may be coplanar with each other) or may have different heights. In particular, as illustrated in FIG. 16, the upper surface 260C1 of the covering member 260C is preferably positioned higher than the upper surface 250C1 of the wavelength conversion member 250C. When the upper surface 260C1 of the covering member 260C is positioned higher than the upper surface 250C1 of the wavelength conversion member 250C, light emitted from the light-emitting element 210, passing through the upper surface 250C1 of the wavelength conversion member 250C, and traveling toward a lateral surface of the light-emitting device 20C can be reflected upward. Accordingly, the light extraction efficiency of the light-emitting device 20C can be improved.

According to an embodiment of the present disclosure, a light-emitting device is less likely to be visually recognized from the outside.

Although embodiments have been described in detail above, the above-described embodiments are non-limiting examples, and various modifications and substitutions can be made to the above-described embodiments without departing from the scope described in the claims.

What is claimed is:

1. A light-emitting device comprising:
a light-emitting element;
a light-transmissive member disposed on the light-emitting element and having an upper surface, a lower surface, and a first recessed portion that opens at the upper surface; and
a first light-shielding member located on the upper surface of the light-transmissive member, wherein:
a lateral surface of the first recessed portion of the light-transmissive member is exposed from the first light-shielding member.

2. The light-emitting device according to claim 1, further comprising:
a second light-shielding member located on a bottom portion of the first recessed portion, wherein:
the lateral surface of the first recessed portion of the light-transmissive member is exposed from the first light-shielding member and the second light-shielding member.

3. The light-emitting device according to claim 1, wherein the first light-shielding member comprises a black filler.

4. The light-emitting device according to claim 3, wherein:
the light-transmissive member comprises metal oxide particles, and
the black filler of the first light-shielding member comprises reduced oxide particles comprising a same metal element as a metal element comprised in the metal oxide particles of the light-transmissive member.

5. The light-emitting device according to claim 1, further comprising:
a wavelength conversion member disposed between the light-emitting element and the light-transmissive member, wherein:
the wavelength conversion member is separated from the first recessed portion.

6. The light-emitting device according to claim 1, wherein the lateral surface of the first recessed portion comprises an inclined surface inclined from an opening of the first recessed portion to a bottom portion of the first recessed portion.

7. The light-emitting device according to claim 1, wherein the first recessed portion has a linear shape in a top view of the light-emitting device.

8. The light-emitting device according to claim 7, wherein the first recessed portion and one or more additional first recessed portions are arranged in a strip pattern in the top view of the light-emitting device.

9. The light-emitting device according to claim 1, further comprising:
a covering member covering a lateral surface of the light-emitting element, wherein:
the light-transmissive member covers an upper surface of the covering member.

10. The light-emitting device according to claim 1, further comprising:
a covering member covering a lateral surface of the light-emitting element and a lateral surface of the light-transmissive member, wherein:
an upper surface of the covering member and the upper surface of the light-transmissive member are coplanar with each other.

11. The light-emitting device according to claim 10, further comprising:
a third light-shielding member located on the upper surface of the covering member.

12. The light-emitting device according to claim 11, wherein
the covering member has a second recessed portion that opens at the upper surface thereof, and
a lateral surface of the second recessed portion of the covering member is exposed from the third light-shielding member.

13. The light-emitting device according to claim 12, wherein the first recessed portion and the second recessed portion are located on a same straight line in a top view.

14. The light-emitting device according to claim 5, further comprising:
a covering member covering a lateral surface of the light-emitting element and a lateral surface of the wavelength conversion member, wherein:
the light-transmissive member covers an upper surface of the covering member.

15. The light-emitting device according to claim 14, wherein the upper surface of the covering member is positioned higher than an upper surface of the wavelength conversion member.

16. A light-emitting module comprising:
a light-emitting device; and
a lens disposed on the light-emitting device, wherein:
the light-emitting device comprises:
a light-emitting element,
a light-transmissive member disposed on the light-emitting element, and having an upper surface, a lower surface, and a first recessed portion that opens at the upper surface, and
a first light-shielding member located on the upper surface of the light-transmissive member, and
a lateral surface of the first recessed portion of the light-transmissive member is exposed from the first light-shielding member.

17. A mobile device comprising:
a display; and
a light-emitting module disposed on a same side of the mobile device as the display in a top view, wherein
the light-emitting module comprises:
a light-emitting device, and
a lens disposed on the light-emitting device,
the light-emitting device comprises:
a light-emitting element,
a light-transmissive member disposed on the light-emitting element, and having an upper surface, a lower surface, and a first recessed portion that opens at the upper surface, and
a first light-shielding member located on the upper surface of the light-transmissive member, and
a lateral surface of the first recessed portion of the light-transmissive member is exposed from the first light-shielding member.
